(19) United States
(12) Patent Application Publication
(10) Pub. No.: US 2018/0034243 A1
(43) Pub. Date: Feb. 1, 2018

(54) MONOLITHIC DIODE LASER ARRANGEMENT AND METHOD FOR PRODUCING THE MONOLITHIC DIODE LASER

(71) Applicant: DILAS DIODENLASER GMBH, Mainz (DE)

(72) Inventors: MARC KELEMEN, GUNDELFINGEN (DE); SASCHA HILZENSAUER, FREIBURG (DE); JUERGEN GILLY, GUNDELFINGEN (DE); PATRICK FRIEDMANN, SIMONSWALD (DE); JENS BIESENBACH, MAINZ (DE)

(21) Appl. No.: 15/728,922

(22) Filed: Oct. 10, 2017

Related U.S. Application Data
(63) Continuation of application No. PCT/EP2016/057452, filed on Apr. 5, 2016.

(30) Foreign Application Priority Data
Apr. 9, 2015 (DE) 102015105438.8

(51) Int. Cl. H01S 5/40; H01S 5/20; H01S 5/028; H01S 5/026; H01S 5/042; H01S 5/02

(52) U.S. Cl. CPC H01S 5/4018; H01S 5/0422; H01S 5/0216; H01S 5/028; H01S 5/026; H01S 5/2086; H01S 2301/176

(57) ABSTRACT

A monolithic diode laser arrangement contains a plurality of individual emitters which are arranged adjacent to one another on a common supporting substrate and which in each case have contact windows for electrical contact which are arranged on the respective individual emitters on a front face opposite the supporting substrate. A method for producing such a diode laser arrangement and a laser device having such a diode laser arrangement are further described.

This application is a continuation, under 35 U.S.C. § 120, of copending international application No. PCT/EP2016/057452, filed Apr. 5, 2016, which designated the United States; this application also claims the priority, under 35 U.S.C. § 119, of German patent application No. DE 10 2015 105 438.8, filed Apr. 9, 2015; the prior applications are herewith incorporated by reference in their entirety.

### BACKGROUND OF THE INVENTION

### Field of the Invention

The invention relates to a monolithic diode laser arrangement, a method for producing such a monolithic diode laser arrangement, and a laser device containing such a monolithic diode laser arrangement.

Diode laser arrangements or diode laser arrays for diode lasers having high power densities find diverse applications in a wide variety of fields, such as, for instance, the optical pumping of solid-state, fiber and disk lasers, direct material processing or medical therapy or diagnostics.

The optical power required in these applications typically cannot be provided by an individual laser diode or by an individual emitter. It is therefore customary for a multiplicity of individual emitters to be electrically connected in parallel or in series in a diode laser arrangement.

The known diode laser arrangements concerning the series connection of individual emitters are typically constructed from a multiplicity of individual emitters which are spatially separated from one another and which are subsequently connected in series. In this respect, such components do not have a monolithic construction. This results in a comparatively complex optical alignment which has to be carried out individually for each individual emitter. Moreover, the individual emitters normally have to be applied on separate heat sinks. The number of individual emitters interconnected with one another in this way in the diode laser arrangement is usually in the region of less than twenty items. What is advantageous about such embodiments is the operating current of the diode laser arrangement, which corresponds to the operating current of each individual emitter independently of the number of individual emitters in the arrangement. The voltage present at the diode laser arrangement having the series connection corresponds to the sum of the voltages present at the individual emitters.

In the case of diode laser arrangements having individual emitters interconnected in parallel, monolithic embodiments, so-called diode laser arrays or bars, are known, in which the electrical contacting is effected on opposite sides of the individual emitters. Such monolithic constructions enable simpler optical system mounting since only a single optical system per collimation direction is required for the entire diode laser arrangement. A major disadvantage of the diode laser arrangement having the parallel connection of individual emitters is the high currents necessary for operation, corresponding to the sum of the currents flowing through the respective individual emitters.

### SUMMARY OF THE INVENTION

Proceeding from this prior art, it is an object of the present invention to specify an improved diode laser arrangement in which the disadvantages mentioned above are largely avoided. Furthermore, it is an object of the invention to specify a method for producing a diode laser arrangement improved in this way.

A monolithic diode laser arrangement contains a multiplicity of individual emitters arranged alongside one another on a common carrier substrate and each having contact windows for electrical contacting, which are arranged at the respective individual emitters at a front side opposite the carrier substrate.

In order to generate the laser light, each individual emitter has a recombination zone situated between a p and an n doped region of a multilayered epitaxial structure of the respective individual emitter. The epitaxial structure is a multilayered construction of epitaxial layers that is applied on an epitaxial substrate. The epitaxial substrate is not completely covered by the epitaxial structure, such that the epitaxial substrate is also electrically contactable by a front-side contact window.

As epitaxial substrate, provision is preferably made of a III V semiconductor material, in particular GaAs, InP or GaSb, which particularly advantageously has an n type doping.

The epitaxial structure contains at least one p doped cladding layer and at least one n doped cladding layer. In one concrete exemplary embodiment of the invention, the epitaxial layers applied as epitaxial structure on the epitaxial substrate contains the sequence of an n doped cladding layer, an n side waveguide layer, a quantum well structure, a p side waveguide structure, a p doped cladding layer and a p doped contact layer. The recombination processes that generate the laser light take place in the quantum well structure in this preferred exemplary embodiment, the quantum well structure being formed for example by a layer containing InGaAs, InGaAsP, GaInSb and/or GaInAsSb. In accordance with possible exemplary embodiments, the doped cladding layers and/or the waveguide layers consist of AlGaAs, InGaAsP, AlGaAsSb. In accordance with possible exemplary embodiments, the p doped contact layer consists of GaAs, GaSb, InP and/or InGaAs.

For electrically contacting the p doped cladding layer, a p type contact window is arranged on the front side on the epitaxial structure. Correspondingly, the electrical contacting of the n doped cladding layer is effected via an n type contact window arranged on the front side on the epitaxial substrate in the region in which the epitaxial substrate is not covered by the epitaxial structure.

The monolithic, that is to say substantially integral, construction of the diode laser arrangement results from a process of singulating a spatially continuous structure that determines the arrangement of the individual emitters on the carrier substrate. The spatially continuous structure is formed by a wafer stack having a corresponding layer structure, which wafer stack is subsequently singulated by scribing and cleavage, that is to say is divided into the individual diode laser arrangements.

The diode laser arrangement according to the invention can thus be produced cost-effectively in large numbers. Furthermore, the arrangement of the individual emitters on the common carrier substrate enables simplified optical system mounting since only one optical system per collimation direction is required for the entire diode laser arrangement. At the same time, the arrangement of the contact windows provided for electrical contacting on the front side opposite the carrier substrate particularly advantageously enables the series connection of the individual emitters. The operating current flowing through the entire diode laser arrangement thus corresponds to the operating current flowing through each of the individual emitters, such that a limitation of the diode laser arrangement in this respect regarding the number of individual emitters provided for generating the laser light is omitted. Particularly powerful diode laser arrangements can thereby be provided as a result. For cooling the entire diode laser arrangement, preferably only one heat sink is provided, in order to minimize the mounting outlay.

In preferred embodiments, the individual emitters of the monolithic diode laser arrangement are connected to the carrier substrate indirectly via a bond plane arranged there between. Such exemplary embodiments are advantageous in particular with regard to their production, since two multilayered layer structures can be connected to one another by the bond plane, which layer structures prior to bonding, with regard to their layer thicknesses, can be selectively adapted to the specific requirements of the diode laser arrangement to be produced. The bond plane consists for example of materials such as gold, aluminum, germanium, tin, a photosensitive epoxy resin, benzocyclobutene (BCB), a polyimide and/or a spin-on glass (SOG).

Since, in accordance with possible exemplary embodiments of the invention, in particular electrically conductive materials can be used for the bonding, an insulation layer is preferably arranged between the individual emitters and the bond layer, which thus provides a rear-side electrical insulation of the individual emitters. The individual emitters are interconnected via the contact windows arranged on the front side.

Particularly preferably, the contact windows of the individual emitters are connected by metallic coatings in such a way that the individual emitters are electrically connected in series with one another. Applying the metallic coating is carried out at the wafer level in a single production step, that is to say before singulating the spatially continuous structure defining the arrangement of the individual emitters on the carrier substrate. Additional wire bonding processes on the rear side, that is to say on the side of the carrier substrate, are superfluous for this purpose.

Preferably, one of the p type contact windows of at least one of the individual emitters is electrically conductively connected to the n type contact window of the individual emitter adjacent to the at least one individual emitter by the metallic coatings. The metallic coatings thus ensure the interconnection of the individual emitters in series, wherein the electrically conductive connections provided for the current flow are arranged exclusively on the front side at the diode laser arrangement.

In a method for producing a monolithic diode laser arrangement described above, the spatially continuous structure that determines the formation of the arrangement of the individual emitters on the carrier substrate is implemented in a structuring step at the wafer level. In the structuring step, the individual structures assigned to the individual emitters are thus formed from a multilayered basic carrier containing a carrier substrate. The formation of the individual structures in the structuring step is implemented in this case in such a way that said individual structures are not detached from the carrier substrate or from the carrier substrate layer in the process. The front sides of the individual structures opposite the carrier substrate are provided for forming contact windows.

After the singulation of the structured wafer stack, that is to say after the singulation of the spatially continuous structure that determines the arrangement of the individual emitters on the carrier substrate, the carrier layer forms the carrier substrate of the diode laser arrangement. Correspondingly, the individual structures assigned to the respective individual emitters, after singulation, form the individual emitters for generating the laser light.

In one of the preferred exemplary embodiments mentioned above, the individual emitter contains an epitaxial structure including the recombination zone, the epitaxial structure being applied on an epitaxial substrate. Correspondingly, the multilayered basic carrier provided for structuring contains at least one epitaxial structure layer, an epitaxial substrate layer and the carrier substrate layer, which are applied on a carrier plate, which gives the basic carrier the necessary mechanical stability during the production process.

In the structuring step, the epitaxial structure layer and the epitaxial substrate layer of the basic carrier are removed in sections for forming the individual structures. This is typically carried out by an etch, also called separation etch, in which a plurality of individual structures arranged on the carrier substrate layer are formed without said individual structures being detached from the carrier substrate layer. The individual structures each comprise epitaxial structures arranged on epitaxial substrates.

Preferably, in the structuring step, a so-called strip etch is additionally carried out, in which contact strips for current injection are introduced into the epitaxial structure layer. The contact strip can be formed for example as an elevated region centrally on the epitaxial structure.

Preferably, the epitaxial structure layer is furthermore removed, or removed by etching, in sections to the level of the epitaxial substrate layer in the structuring step in such a way that the epitaxial substrate layer is not completely covered by the epitaxial structure layer. The structuring step can be carried out in an isolation etch, for example, in which the epitaxial structure layer is selectively removed from the underlying epitaxial substrate layer in specific regions in order to enable a subsequent front-side electrical contacting of the epitaxial substrate via contact windows arranged in said regions.

Preferably, the structuring step, in particular the separation, strip and/or isolation etch, comprises a lithography. Such structuring methods are sufficiently known in the field of semiconductor fabrication and need no further explanation. The etches are preferably carried out dry-chemically, in particular by plasma etching (ICPRIE or RIE method), but they can also be carried out wet-chemically.

In accordance with one possible exemplary embodiment, the spatially continuous structure formed in the structuring step is passivated or coated over the whole area with an electrically insulating passivation layer in a passivation step which follows, preferably directly follows, the structuring step. The passivation layer consists of SiN or SiO₂, for example.

Afterward, the passivation layer is preferably removed in sections by means of a further dry or wet-chemical etch. This is done for exposing the contact windows in order to enable a front-side interconnection of the individual emitters. Correspondingly, the previously passivated epitaxial structure is exposed again in sections for forming p type contact windows and the previously passivated epitaxial substrate is exposed again in sections for forming n type contact windows.

Particularly preferably, the contact windows are provided with metallic coatings in a succeeding, in particular directly succeeding, metallization step in such a way that the individual structures assigned to the individual emitters are connected in series. The interconnection of the individual structures is thus effected by the application of correspondingly conductive metallic coatings at the wafer level, i.e. for a multiplicity of diode laser arrangements formed later by singulation in a single manufacturing step. Subsequent complex separate contacting of the individual emitters can thus be obviated.

Particularly preferably, the metallization step is carried out in two stages. In a first metallization step, first metallic coatings are applied on the spatially continuous structure which forms the diode laser arrangement after singulation. The first metallic coating contacts only the n type contact windows on the epitaxial substrate and preferably consists of a plurality of metallic layers, such as, for example, an AuGeNi or a TiPtAu metal sequence. After the first metallic coating has been applied, it is subjected to a suitable alloying method. In a second metallization step succeeding that, at least one second metallic coating is applied, which connects at least one of the first metallic coatings contacting the n type contact windows to a p type contact window arranged on the epitaxial structure of an adjacent individual structure. In other words, a series connection of at least two individual structures assigned to individual emitters is brought about by the electrically conductive connection available as a result of the second metallic coating. The second metallic coating, too, preferably contains a plurality of metallic layers, in particular a combination of titanium, platinum and gold, which are deposited for example by means of physical vapor deposition, particularly preferably by electron beam evaporation, or by a sputtering method. Such methods can also be used for the deposition of the first metallic coating. In other exemplary embodiments, the first and/or second metallic coating are/is deposited electrolytically; in particular, the first and/or second metallic coating can contain at least one gold layer deposited electrolytically. Furthermore, in exemplary embodiments in which the diode laser arrangement is arranged on a heat sink later by hard soldering (e.g. AuSn solder), a corresponding platinum barrier is taken into account as a diffusion barrier for the hard solder.

In preferred exemplary embodiments, the basic carrier, which, in the structuring step, experiences a spatially continuous structure determining the later diode laser arrangement, is formed from at least two layer structures that are connected to one another by bonding in a bonding step. This has the advantage that the layer thickness of the layers constituting the two layer structures can be selectively adapted before the structuring step.

Particularly preferably, the first layer structure contains the sequence of the epitaxial structure layer, the epitaxial substrate layer, an insulation layer and a first bond layer. The insulation layer serves for electrically insulating the epitaxial substrate layer arranged there above from the bond layer, which is generally electrically conductive. The first layer structure, on the part of the epitaxial structure layer, is applied on a further carrier plate, which imparts mechanical stability to the first layer structure in the previous method steps and is removed after the first bond layer has been connected to a second bond layer of the second layer structure in the bonding step, that is to say the two layer structures forming the basic carrier have thus been connected.

The insulation layer preferably consists of SiN or SiO₂. The insulation layer is applied on the epitaxial structure layer, which was preferably thinned in a previous method step.

The arrangement of the first layer structure on a further carrier plate in a method step that precedes at least the bonding provides the necessary stability, such that the epitaxial substrate layer can be thinned to a minimum possible substrate thickness, which is preferably between 50 μm and 100 μm residual thickness. This method step firstly ensures a minimum etching depth for the later separation etch during the separation step; secondly, a good cleavage face for the singulation of the wafer stack formed into diode laser arrangements or diode laser arrays is provided.

The second layer structure contains the second bond layer and the carrier substrate layer. The second layer structure, preferably on the part of the carrier substrate layer, is applied on the carrier plate and correspondingly thinned before the second bond layer is applied. In particular, the layer thickness of the carrier substrate layer can likewise be reduced to between 50 μm and 100 μm residual thickness. In particular, both doped and undoped III V semiconductor materials are suitable as materials of the carrier substrate layer. In other exemplary embodiments, a silicon substrate is used as carrier substrate layer.

As first and/or second bond layer, thin layers composed, in particular, of Au, Al, Ge, Sn, SU₈, BCB, polyimide and/or SOG are deposited on the insulation layer and/or on the carrier substrate layer. The two metal planes forming the first and second bond layers are connected to one another in the bonding step. The bond methods used for this purpose preferably contains eutectic bonding, adhesion bonding or thermo compressive bonding.

The monolithic diode laser arrangement is formed by singulating the spatially continuous structure formed substantially in the structuring step, wherein the spatially continuous structure is coated, if appropriate, in the metallization step.

A laser device according to the invention contains at least one of the diode laser arrangements described above, such that firstly reference is made to the explanations in respect thereof. Such laser devices can be used in particular for direct material processing or in the medical field, for example in the field of medical therapy or diagnosis. In accordance with particularly preferred exemplary embodiments, the laser device contains at least one diode laser arrangement having a plurality of series-connected individual emitters arranged on a common carrier substrate. The at least one diode laser arrangement has an optical system per collimation direction.

In other exemplary embodiments, the laser device contains a plurality of diode laser arrangements that are electrically connected in parallel and/or in series with one another in order to provide high powers.

Particularly preferably, a laser device contains an optical medium into which the laser light generated by the diode laser arrangement can be coupled for optically pumping the optical medium. The diode laser arrangement is thus part of a pump module of the laser device, which can be embodied for example as a solid-state, fiber or disk laser.

Other features which are considered as characteristic for the invention are set forth in the appended claims.

Although the invention is illustrated and described herein as embodied in a monolithic diode laser arrangement, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, sectional view showing a first and second layer structure, before the connection thereof to form a basic carrier;

FIG. 2 is a sectional view showing the basic carrier structured in a structuring step to form a spatially continuous structure defining a diode laser arrangement;

FIG. 3 is a sectional view showing the spatially continuous structure passivated in a passivation step;

FIG. 4 is a sectional view showing the passivated structure provided with a first metallic coating in a metallization step; and

FIG. 5 is a sectional view showing the passivated structure provided with a first metallic coating, or the diode laser arrangement.

### DETAILED DESCRIPTION OF THE INVENTION

Mutually corresponding parts are provided with the same reference signs in all the figures.

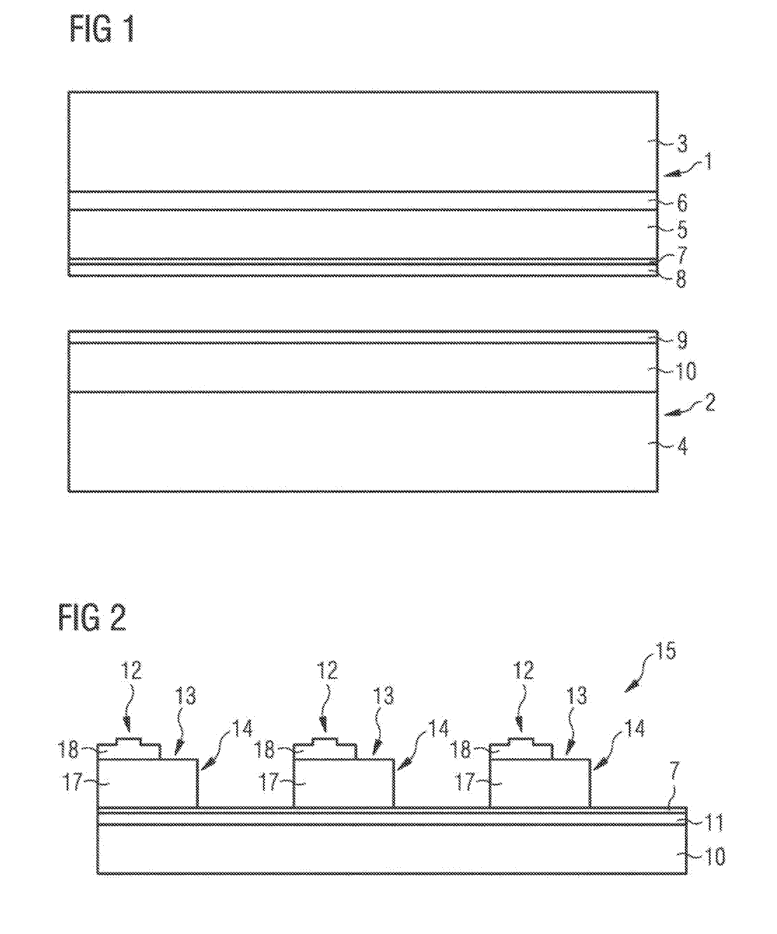

Referring now to the figures of the drawings in detail and first, particularly to FIG. 1 thereof, there is shown a first layer structure 1 and a second layer structure 2 in a schematic sectional illustration. The layer structures respectively contain a plurality of layers of semiconductor materials and/or metals arranged on carrier plates 3, 4.

The first layer structure has an epitaxial substrate layer 5, which consists of a III V semiconductor material. In the exemplary embodiment shown the epitaxial substrate layer 5 consists of n doped gallium arsenide, n GaAs. In order to produce a high-power diode laser arrangement 100 on the basis of a GaAs substrate, a first production step involves depositing on the epitaxial substrate layer 5 successively an n doped cladding layer (e.g. AlGaAs, InGaAsP, AlGaAsSb), an n side waveguide layer (e.g. AlGaAs, InGaAsP, AlGaAsSb), a quantum well structure (e.g. InGaAs, InGaAsP, GaInSb, GaInAsSb), in which the recombination processes that generate the laser light take place, a p side waveguide structure (e.g. AlGaAs, InGaAsP, AlGaAsSb), a p doped cladding layer (e.g. AlGaAs, InGaAsP, AlGaAsSb), and a p doped contact layer (e.g. GaAs, GaSb, InP, InGaAs). The totality of these layers deposited on the epitaxial substrate layer 5 is designated hereinafter as epitaxial structure layer 6.

In a second manufacturing step, the epitaxial substrate layer 5, on the part of the epitaxial structure layer 6, is temporarily bonded onto a first carrier plate 3, such that the epitaxial structure layer 6 lies between the first carrier plate 3 and the epitaxial substrate layer 5. The epitaxial substrate layer 5 is subsequently thinned to a minimum possible substrate thickness by conventional processes that are sufficiently known in the field of semiconductor fabrication and need no further explanation. As a result, inter alia the etching depth necessary in a subsequent structuring step is reduced and the later singulation of the wafer structure comprising the first and second layer structures 1, 2 into diode laser arrangements 100 is facilitated. A residual thickness of the epitaxial substrate 5 of between 50 μm and 100 μm should be striven for.

In a third manufacturing step, a carrier substrate layer 10 of the second layer structure 2 is likewise bonded onto a second carrier plate 4 and likewise thinned to approximately 50-100 μm residual thickness. The carrier substrate layer 10 consists of a carrier substrate that is a doped III V semiconductor substrate in the exemplary embodiment shown.

In other exemplary embodiments, undoped III V semiconductor substrates or silicon substrates can also be used.

In a fourth manufacturing step, the thinned epitaxial substrate 5 is coated with an electrically insulating insulation layer 7, which consists of SiN in the preferred exemplary embodiment shown. In an alternative exemplary embodiment relative thereto, the insulation layer 7 consists of SiO₂.

A thin first bond layer 8 which consists of gold (Au) is deposited on the insulation layer 7. Correspondingly, a thin second bond layer 9, which likewise consists of gold, is deposited on the carrier substrate layer 10.

In other exemplary embodiments, the first and/or second bond layer(s) 8, 9 consist(s) of Al, Ge, Sn, SU₈, BCB, polyimide or SOG.

FIG. 2 shows the thinned epitaxial substrate and carrier substrate layers 5, 10 applied respectively on carrier plates 3, 4 before the bonding. The insulation layer 7 has been deposited on the epitaxial substrate layer 5, the insulation layer carrying the first bond layer 8. The carrier substrate layer 10 of the second layer structure 2 carries the second bond layer 9.

In a fifth manufacturing step, the first layer structure 1 is bonded on the side having the first bond layer 8 onto the thinned and coated carrier substrate layer 10. After bonding, the two bond layers 8, 9 constitute a common bond plane 11, which is shown in FIGS. 2 to 5. The first and second bond layers 8, 9 are connected to one another by eutectic bonding in the exemplary embodiment shown; adhesion bonding or thermo compressive bonding can also be used in other exemplary embodiments. A permanently bonded wafer stack or basic carrier containing the first and second layer structures 1, 2 is thus formed as a result. The first carrier plate 3, situated on the side of the epitaxial structure layer 6 of the basic carrier, is detached from the latter and the topmost layer of the epitaxial structure layer 6, formed by the p doped contact layer, is cleaned.

The bonded basic carrier is then structured in a structuring step by lithography methods that are customary for the production of diode laser arrangements 100, such that the basic carrier acquires the spatially continuous structure 15 shown in FIG. 2. For this purpose, a sixth method step involves firstly forming contact strips 12 for current injection by etching the p type contact layers of the epitaxial structure layer 6. The width of the contact strips 12 defined in the strip etch defines the extent of the electric field and the current injection area.

Afterward, isolation trenches 13 are introduced into the epitaxial structure layer 6 by means of an isolation etch. For this purpose, the epitaxial structure layer 6 is removed from the epitaxial substrate layer 5 in sections by etching. The separation of the respective individual structures 14 assigned to individual emitters 101 of the diode laser arrangement 100 is carried out by a separation etch, which consists in an etch of the basic carrier as far as the insulation layer 7 arranged above the bond plane 11. All etches are performed dry-chemically, for example by ICPRIE or RIE methods; in other exemplary embodiments, the etches of the structuring step can also be carried out wet-chemically.

In the structuring step described above, the diode laser arrangement 100 substantially acquires its spatially continuous structure 15 containing a multiplicity of individual structures 14 arranged on the carrier substrate layer 10. After the singulation of the spatially continuous structure 15 by scribing and cleavage of the wafer stack, the individual structures 14 correspondingly form the individual emitters 101 of the diode laser arrangement 100, which is illustrated in FIG. 5. The individual structures 14 respectively comprise epitaxial substrates 17 covered in sections by epitaxial structures 18. As described above, the epitaxial substrates 17 and epitaxial structures 18 arise from the epitaxial substrate layer 5 and the epitaxial structure layer 6 as a result of the etching of the basic carrier in the structuring step. With regard to the layer sequence, the epitaxial structure 18 is thus identical to the epitaxial structure layer 6.

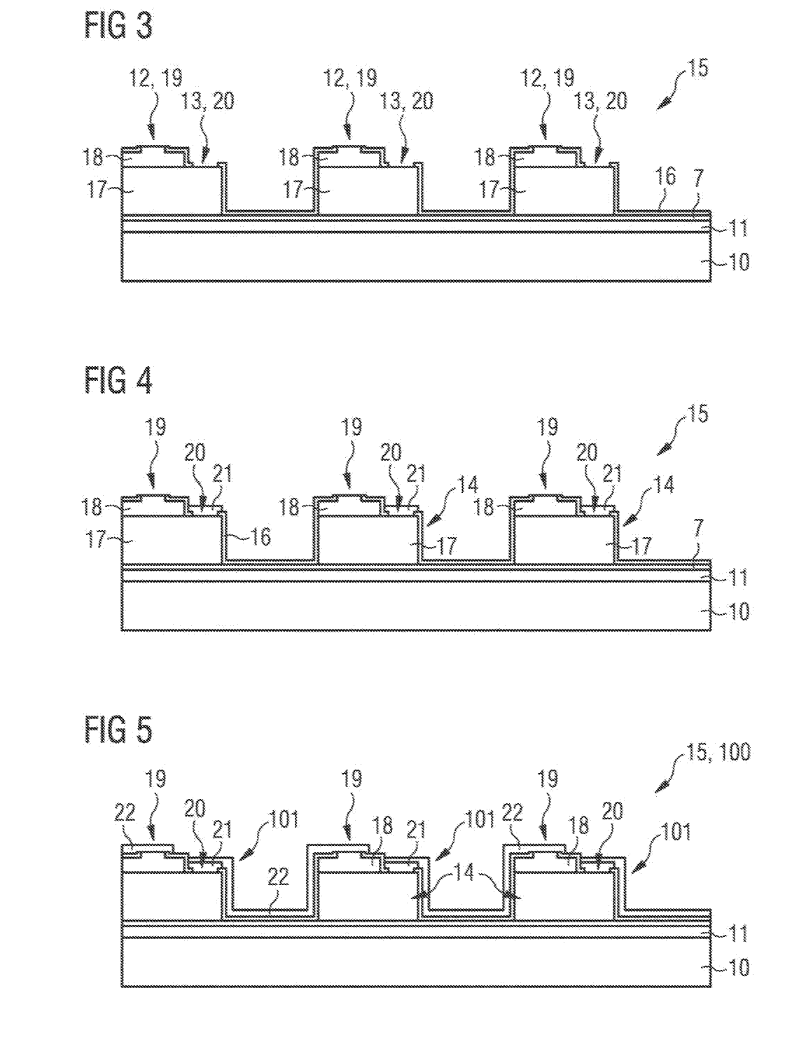

FIG. 3 illustrates a seventh method step, which follows the structuring step and in which the structured surface of the spatially continuous structure 15 is firstly passivated over the whole area with an electrically insulating passivation laser 16 consisting of SiN or SiO₂, for example.

Afterward, the passivation layer 16 is structured in sections on the epitaxial substrates 17 and the epitaxial structures 18 by a dry or wet-chemical etching step. The contact strip 12 of the epitaxial structures 18 is exposed for forming p type contact windows 19. Correspondingly, a passivation layer 16 in the region of the isolation trenches 13 is removed in sections for forming n type contact windows 20.

In an eighth step, the spatially continuous structure 15 is metalized. The metallization step is in two stages in the example shown. First, only the N metallization is effected at the n type contact windows 20 by the application of, for example, AuGeNi or TiPtAu metal sequences and subsequent suitable alloying methods, as illustrated in FIG. 4. In this case, a first metallic coating 21 is applied in the region of the n type contact windows 20, the first metallic coating serving for later contacting with a second metallic coating 22.

After the application of the final second metallic coating 22 consisting of a combination of titanium, platinum and gold, a layer structure corresponding to the illustration in FIG. 5 is formed. The second metallic coating 22 is applied by a physical vapor deposition method; in other exemplary embodiments, a sputtering method can also be used for this purpose. The second metallic coating 22 respectively connects an n type contact window 20 to a p type contact window 19 of an adjacent individual structure 17 or of an individual emitter 101. In other words, the second metallic coating 22 thus applied brings about an interconnection of the individual emitters 101 in series.

In a tenth method step, the carrier plate 10 is removed from the carrier substrate layer 10. The completed wafer has the spatially continuous structure 15 shown in FIG. 5. The wafer is cleaved by scribing and cleavage of the wafer stack parallel to the plane of the drawing and is thereby singulated into the individual diode laser arrangements 100. In this case, the cleavage faces oriented perpendicularly to the plane of the drawing form exit sides for the laser emission, from which semiconductor oxides and contaminants are subsequently cleaned by suitable methods and which are subsequently encapsulated and coated with reflection layers by means of suitable methods.

In a last step, the series-connected diode laser arrangements 101 with the epitaxial structure 18 are soldered onto correspondingly structured heat sinks by soft solders (e.g. indium solder) or hard solders (e.g. AuSn solder).

The diode laser arrangement 101 thus formed is particularly suitable for high-power laser devices. For this purpose, in particular a plurality of diode laser arrangements 101 can be connected in series or in parallel. The laser light provided by the diode laser arrangement 101 can be used directly, for example in the field of medical therapy or diagnostics, or can be used for optically pumping an optical medium. Correspondingly, laser devices in which the diode laser arrangement 101 is part of a pump module for optically pumping the optically active medium are likewise the subject matter of the present invention in the same way as laser devices in which the light provided by the diode laser arrangement 101 is used directly.

The invention has been described above with reference to preferred exemplary embodiments. It goes without saying, however, that the invention is not restricted to the concrete configuration of the exemplary embodiments shown; rather, the competent person skilled in the art can derive variations with reference to the description, without departing from the essential basic concept of the invention.

The following is a summary list of reference numerals and the corresponding structure used in the above description of the invention:

| | |
|---|---|
| 1 | First layer structure |
| 2 | Second layer structure |
| 3 | First carrier plate |
| 4 | Second carrier plate |
| 5 | Epitaxial substrate layer |
| 6 | Epitaxial structure layer |
| 7 | Insulation layer |
| 8 | First bond layer |
| 9 | Second bond layer |
| 10 | Carrier substrate layer |
| 11 | Bond plane |
| 12 | Contact strip |
| 13 | Isolation trench |
| 14 | Individual structure |
| 15 | Structure |
| 16 | Passivation layer |
| 17 | Epitaxial substrate |
| 18 | Epitaxial structure |
| 19 | p Type contact window |
| 20 | n Type contact window |
| 21 | First metallic coating |
| 22 | Second metallic coating |
| 100 | Diode laser arrangement |
| 101 | Individual emitter |

1. A monolithic diode laser configuration, comprising:
a common carrier substrate; and
a plurality of individual emitters disposed alongside one another on said common carrier substrate and each having contact windows for electrical contacting, said contact windows disposed at a front side of said individual emitters opposite said common carrier substrate, each of said individual emitters containing:
an epitaxial substrate; and
a multilayered epitaxial structure applied on said epitaxial substrate such that said epitaxial substrate is not completely covered by said multilayered epitaxial structure, said multilayered epitaxial structure having at least one p-doped cladding layer and at least one n-doped cladding layer, wherein said multilayered epitaxial structure having a p-type contact window for electrically contacting said p-doped cladding layer and disposed on a front side of said multilayered epitaxial structure and wherein said epitaxial substrate having an n-type contact window for electrically contacting said n-doped cladding layer and disposed on a front side on said epitaxial substrate in a region in which said epitaxial substrate is not covered by said multilayered epitaxial structure.

2. The monolithic diode laser configuration according to claim 1, further comprising a bond plane, said individual emitters are connected to said common carrier substrate indirectly via said bond plane disposed between said individual emitters and said common carrier substrate.

3. The monolithic diode laser configuration according to claim 2, further comprising an insulation layer, said individual emitters are electrically insulated from said bond plane by means of said insulation layer disposed between said individual emitters and said bond plane.

4. The monolithic diode laser configuration according to claim 1, further comprising metallic coatings, said contact windows of said individual emitters are connected by means of said metallic coatings in such a way that said individual emitters are electrically connected in series with one another.

5. The monolithic diode laser configuration according to claim 4, wherein said p-type contact window of at least one of said individual emitters is electrically conductively connected to said n-type contact window of an individual emitter adjacent to said at least one individual emitter by means of said metallic coatings.

6. A method for producing a monolithic diode laser configuration, which comprises the step of:
forming a spatially continuous structure determining a configuration of individual emitters on a carrier substrate in a structuring step in which individual structures assigned to the individual emitters are formed from a multilayered basic carrier containing the carrier substrate, without the individual structures being detached from the carrier substrate, and front sides of the individual structures opposite the carrier substrate are provided for forming contact windows.

7. The method according to claim 6, wherein the multilayered basic carrier has at least one epitaxial structure layer, an epitaxial substrate layer and a carrier substrate layer, which are applied on a carrier plate.

8. The method according to claim 7, which further comprises removing the epitaxial structure layer and the epitaxial substrate layer of the multilayered basic carrier in sections in the structuring step for forming the individual structures.

9. The method according to claim 7, which further comprises introducing contact strips for current injection into the epitaxial structure layer in the structuring step.

10. The method according to claim 7, which further comprises removing the epitaxial structure layer in sections to a level of the epitaxial substrate layer in the structuring step in such a way that the epitaxial substrate layer is not completely covered by the epitaxial structure layer.

11. The method according to claim 6, wherein the structuring step contains a lithography.

12. The method according to claim 6, which further comprising passivating the spatially continuous structure formed in the structuring step over a whole area with a passivation layer in a passivation step.

13. The method according to claim 12, which further comprises removing the passivation layer in sections by means of a dry or wet-chemical etch for exposing the contact windows.

14. The method according to claim 6, which further comprises providing the contact windows with metallic coatings in a metallization step such that the individual structures assigned to the individual emitters are connected in series.

15. The method according to claim 14, which further comprises carrying out the metallization step in two stages and, in a first metalization step, first metallic coatings are applied on the spatially continuous structure, which contact n-type contact windows disposed on an epitaxial substrate, and, in a second metalization step, at least one second metallic coating is applied, which connects at least one of the first metallic coatings that contact the n-type contact windows to a p-type contact window disposed on an epitaxial structure of an adjacent individual structure.

16. The method according to claim 6, which further comprises forming a multilayered basic carrier from at least first and second layer structures that are connected to one another by means of bonding in a bonding step.

17. The method according to claim 16, wherein the first layer structure contains a sequence of an epitaxial structure layer, an epitaxial substrate layer, an insulation layer and a first bond layer, wherein the first layer structure, on a part of the epitaxial structure layer, is applied on a further carrier plate, which is removed after the first bond layer has been connected to a second bond layer of the second layer structure in the bonding step.

18. The method according to claim 17, wherein the second layer structure contains the second bond layer and a carrier substrate layer, wherein the second layer structure, on a part of the carrier substrate layer, is applied on a carrier plate.

19. The method according to claim 7, which further comprises forming the monolithic diode laser configuration by means of singulating the spatially continuous structure.

20. A laser device, comprising:
a diode laser configuration, containing:
a common carrier substrate; and
a plurality of individual emitters disposed alongside one another on said common carrier substrate and each having contact windows for electrical contacting, said contact windows disposed at a front side of said individual emitters opposite said common carrier substrate, each of said individual emitters containing:
an epitaxial substrate; and
a multilayered epitaxial structure applied on said epitaxial substrate such that said epitaxial substrate is not completely covered by said multilayered epitaxial structure, said multilayered epitaxial structure having at least one p-doped cladding layer and at least one n-doped cladding layer, wherein said multilayered epitaxial structure having a p-type contact window for electrically contacting said p-doped cladding layer and disposed on a front side of said multilayered epitaxial structure and wherein said epitaxial substrate having an n-type contact window for electrically contacting said n-doped cladding layer and disposed on a front side on said epitaxial substrate in a region in which said epitaxial substrate is not covered by said multilayered epitaxial structure.

21. The laser device according to claim 20, wherein said diode laser configuration is disposed for optically pumping an optical medium.
